(19) United States
(12) Patent Application Publication
(10) Pub. No.: US 2020/0176377 A1
(43) Pub. Date: Jun. 4, 2020

(54) ELECTRONIC DEVICE AND METHOD OF MANUFACTURING THE SAME

(71) Applicant: NANYA TECHNOLOGY CORPORATION, New Taipei City (TW)

(72) Inventors: Yu-Ting LIN, New Taipei City (TW); Mao-Ying WANG, New Taipei City (TW); Shing-Yih SHIH, New Taipei City (TW); Hung-Mo WU, New Taipei City (TW); Yung-Te TING, Taoyuan City (TW)

(21) Appl. No.: 16/251,858

(22) Filed: Jan. 18, 2019

Related U.S. Application Data
(60) Provisional application No. 62/773,823, filed on Nov. 30, 2018.

(51) Int. Cl. H01L 23/522; H01L 23/31; H01L 21/768

(52) U.S. Cl. CPC H01L 23/5226; H01L 21/76897; H01L 23/3171

(57) ABSTRACT

The present disclosure provides an electronic device and a method of manufacturing the same. The electronic device includes a multilayer component, at least one contact pad, a passivation layer, a dielectric layer, and a metallic layer. The contact pad is disposed on the multilayer component, the passivation layer covers the multilayer component and the contact pad, and the dielectric layer is disposed on the passivation layer. The metallic layer penetrates through the dielectric layer and the passivation layer and is connected to the contact pad, and the metallic layer discretely tapers at positions of decreasing distance from the contact pad.

### PRIORITY CLAIM AND CROSS-REFERENCE

This application claims the priority benefit of U.S. provisional patent application No. 62/773,823, filed on Nov. 30, 2018. The entirety of the above-mentioned patent application is hereby incorporated by reference herein and made a part of this specification.

### TECHNICAL FIELD

The present disclosure relates to an electronic device and a method of manufacturing the same, and more particularly, to an electronic device with void-free vias and a method of manufacturing the same.

### DISCUSSION OF THE BACKGROUND

The semiconductor integrated circuit (IC) industry has experienced rapid growth. In the course of the IC evolution, functional density has generally increased while geometry size has decreased. This scaling-down process generally provides benefits by increasing production efficiency and lowering associated costs. Such scaling down has also increased the complexity of processing and manufacturing ICs and, for these advances to be realized, similar developments in IC manufacturing are needed.

For example, as the semiconductor industry has progressed into nanometer technology process nodes in pursuit of higher device density, higher performance, and lower costs, challenges in both fabrication and design have resulted in the development of multilayer devices. The multilayer devices may include a plurality of interlayer dielectric layers (ILDs), one or more wiring layers sunk into the interlayer dielectric layers, and one or more vias interposed between two wiring layers. However, as the scaling down continues, it becomes more difficult to form void-free vias due to poor step coverage of contact holes having a high aspect ratio.

This Discussion of the Background section is provided for background information only. The statements in this Discussion of the Background are not an admission that the subject matter disclosed in this Discussion of the Background section constitute prior art to the present disclosure, and no part of this Discussion of the Background section may be used as an admission that any part of this application, including this Discussion of the Background section, constitutes prior art to the present disclosure.

### SUMMARY

One aspect of the present disclosure provides an electronic device. The electronic device includes a multilayer component, at least one contact pad, a passivation layer, a dielectric layer, and a metallic layer. The contact pad is disposed on the multilayer component. The passivation layer covers the multilayer component and the contact pad. The dielectric layer is disposed on the passivation layer. The metallic layer penetrates through the dielectric layer and the passivation layer. The metallic layer is connected to the contact pad and discretely tapers at positions of decreasing distance from the contact pad.

In some embodiments, the metallic layer includes a first plug segment and a second plug segment; the first plug segment is disposed in the passivation layer and in contact with the contact pad, the second plug segment is disposed in the dielectric layer and connected to the first plug segment, and the first plug segment has a first width less than a second width of the second plug segment.

In some embodiments, the first width is in a range between 1.0 and 2.5 μm, and the second width is not less than 5.0 μm.

In some embodiments, the metallic layer further includes a pad segment disposed on the dielectric layer and connected to the second plug segment.

In some embodiments, the metallic layer is a conformal layer.

In some embodiments, the first plug segment, the second plug segment, and the pad segment are integrally formed.

In some embodiments, the passivation layer includes an underlying layer and an overlying layer; the underlying layer is disposed on the multilayer component and the contact pad, and the overlying layer is disposed between the underlying layer and the dielectric layer.

In some embodiments, at least one of the underlying layer and the overlying layer has a thickness in a range between 0.8 and 1.0 μm, and dielectric layer has a thickness in a range between 4.0 and 6.0 μm.

In some embodiments, sidewalls of the dielectric layer and the overlying layer interfaced with the metallic layer are discontinuous.

In some embodiments, a sidewall of the underlying layer interfaced with the metallic layer is continuous with the sidewall of the overlying layer.

Another aspect of the present disclosure provides a method of manufacturing an electronic device. The method includes steps of providing a multilayer component; forming at least one contact pad on the multilayer component; depositing a passivation layer on the multilayer component and the contact pad; creating at least one first hole in the passivation layer to expose the contact pad; depositing a dielectric layer on the passivation layer and into the first hole; removing a portion of the dielectric layer to uncover the contact pad and create at least one second hole in the dielectric layer, wherein a portion of a top surface of the passivation layer is exposed through the second hole; and depositing a metallic layer on the contact pad and the dielectric layer.

In some embodiments, the second hole communicates with the first hole.

In some embodiments, the method further includes a step of conformally depositing a diffusion barrier layer on the dielectric layer and into the second hole and the first hole.

In some embodiments, apertures of the first hole and the second hole gradually increase at positions of increasing distance from the contact pad.

In some embodiments, the aperture of the first hole is in a range between 1.0 and 2.5 μm, and the aperture of the second hole is in a range between 8.0 and 10.0 μm.

In some embodiments, the depositing of the passivation layer includes steps of depositing an underlying layer to cover the multilayer component, and depositing an overlying layer on the underlying layer.

With the above-mentioned configurations of the electronic device, the step coverage of the metallic layer is improved since aspect ratios of a space, constituted of the first hole and the second hole, for filling the metallic layer discretely changes. Thus, the problems of poor step coverage of the metallic layer are avoided, and a good ohmic contact is secured.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1 illustrates a cross-sectional view of an electronic device in accordance with some embodiments of the present disclosure.

FIG. 2 is a flow diagram illustrating a method of manufacturing electronic devices in accordance with some embodiments of the present disclosure.

FIGS. 3 through 20 illustrate cross-sectional views of intermediate stages in the formation of electronic devices in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

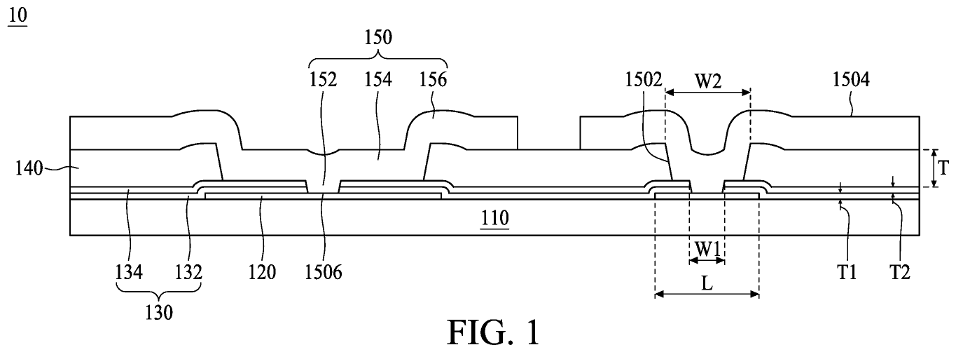

FIG. 1 is a cross-sectional view of an electronic device 10 in accordance with some embodiments of the present disclosure. Referring to FIG. 1, in some embodiments, the electronic device 10 includes a multilayer component 110, one or more contact pads 120 disposed on the multilayer component 110, a passivation layer 130 covering the multilayer component 110 and the contact pads 120, a dielectric layer 140 disposed on the passivation layer 130, and a metallic layer 150 penetrating through the dielectric layer 140 and the passivation layer 130 and connected to the contact pads 120. In some embodiments, a width of the metallic layer 150 discretely tapers, such that sidewalls 1502 of the metallic layer 150 are discontinuous from a top surface 1504 of the metallic layer 150 to a bottom surface 1506 opposite to the top surface 1504, wherein the bottom surface 1506 is in contact with the contact pad 120.

In some embodiments, the contact pads 120 may have a square shape when viewed in a plan view. In some embodiments, the contact pads 120 with smallest dimension have a length L substantially equal to 10.0 μm. In some embodiments, the contact pads 120 are made of conductive material, such as copper, copper alloys, aluminum, or a combination thereof.

In some embodiments, the passivation layer 130 is conformally disposed on the multilayer component 110 and the contact pads 120. In some embodiments, the passivation layer 130 includes an underlying layer 132 in contact with the multilayer component 110 and the contact pad 120 and an overlying layer 134 covering the underlying layer 132. In some embodiments, the underlying layer 132 has a first thickness T1 and the overlying layer 134 has a second thickness T2 substantially equal to or less than the first thickness T1. In some embodiments, the first thickness T1 may be, for example, in a range between 0.5 and 1.5 micrometers (μm), such as about 1.0 μm. In some embodiments, the second thickness T2 is about 0.8 μm. In some embodiments, the underlying layer 132 includes oxide, and the overlying layer 134 includes nitride.

In some embodiments, the dielectric layer 140 is a conformal layer. In some embodiments, the dielectric layer 140 has a thickness T greater than the first thickness T1. In some embodiments, the thickness T may be, for example, in a range between 4.0 and 6.0 μm, such as about 5.5 μm. In some embodiments, the dielectric layer 140 includes nitride.

In some embodiments, the metallic layer 150 includes one or more first plug segments 152 disposed in the passivation layer 130 and one or more second plug segments 154 disposed in the dielectric layer 140 and connected to the first plug segments 152, respectively. In some embodiments, the first plug segments 152 are respectively in contact with the contact pads 120. In some embodiments, the first plug segment 152 has a first width W1 (e.g., a top or a maximum width), and the second plug segment 154 has a second width W2 greater than the first width W1. In some embodiments, the first width W1 and the second width gradually increase at positions of increasing distance from the contact pads 120. In some embodiments, the first width W1 may be, for example, in a range between 1.0 and 2.5 μm, such as about 2.4 μm. In some embodiments, the second width W2 may be not less than 5.0 μm. In some embodiments, the second width W2 is in a range between 8.0 and 10.0 μm.

In some embodiments, the metallic layer 150 further includes one or more pad segments 156 disposed on the dielectric layer 140 and respectively connected to the second plug segment 154. In some embodiments, the first plug segment 152, the second plug segment 154, and the pad segment 156 may be integrally formed. In some embodiments, the metallic layer 150 is a substantially conformal layer.

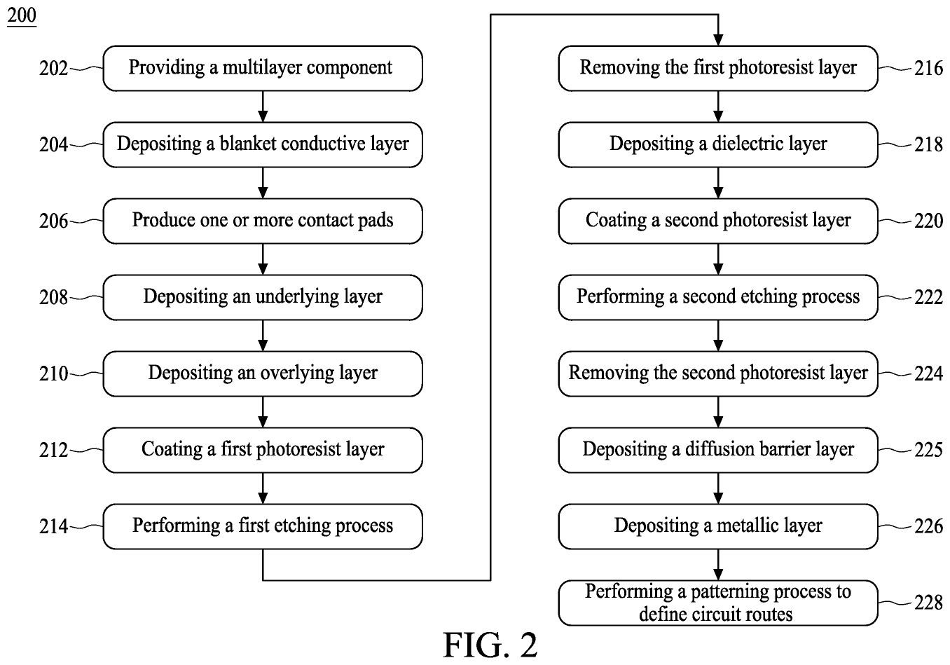

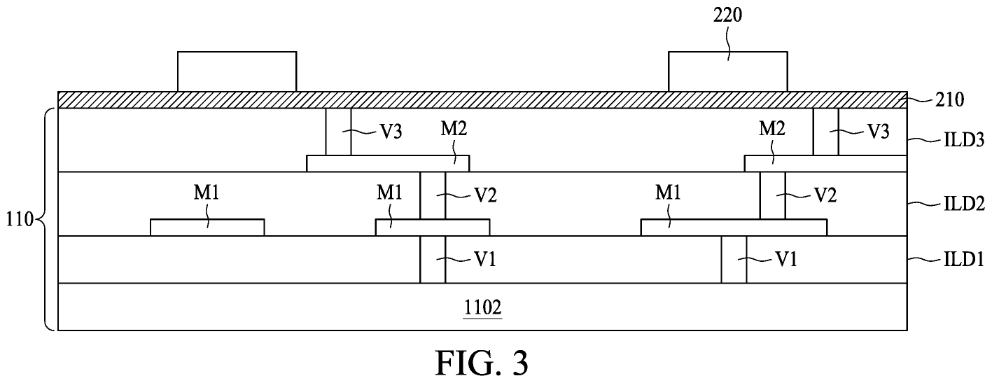

FIG. 2 is a flow diagram illustrating a method 200 of manufacturing electronic devices 10/10A in accordance with some embodiments of the present disclosure. FIGS. 3 to 20 are schematic diagrams illustrating various fabrication stages constructed according to the method 200 of manufacturing the electronic devices 10/10A in accordance with some embodiments of the present disclosure. The stages shown in FIGS. 3 to 20 are also illustrated schematically in the flow diagram in FIG. 2. In the subsequent discussion, the fabrication stages shown in FIGS. 3 to 20 are discussed in reference to the process steps in FIG. 2.

Referring to FIG. 3, a multilayer component 110 is provided according to a step 202 in FIG. 2. In some embodiments, the multilayer component 110 may include a main component 1102 including one or more features, such as transistors, resistors, capacitors, diodes, etc. In some embodiments, the multilayer component 110 may further include an interconnection structure, including alternating stacking of wiring layers M1, M2 and vias V1, V2, V3, disposed over the main component 1102, and one or more interlayer dielectrics ILD1, ILD2, ILD3 encircling the wiring layers M1, M2 and the vias V1, V2, V3.

Next, a blanket conductive layer 210 is deposed on the multilayer component 110 according to a step 204 in FIG. 2. In some embodiments, the blanket conductive layer 210 may include aluminum, aluminum alloys, copper, copper alloys, titanium, tungsten, polysilicon, or a combination thereof. In some embodiments, the blanket conductive layer 210 may be formed by a variety of techniques, e.g., physical vapor deposition (PVD), chemical vapor deposition (CVD), sputtering, and the like.

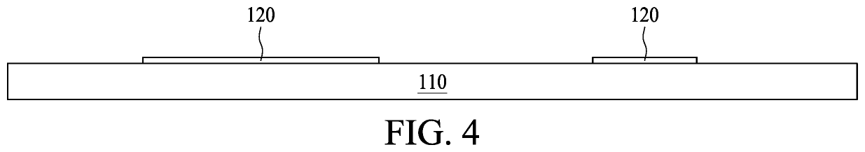

Referring to FIGS. 3 and 4, in some embodiments, the blanket conductive layer 210 is next patterned by an etching process that produces one or more contact pads 120 according to a step 206 in FIG. 2. In some embodiments, the contact pads 120 are formed by steps including (1) providing a mask layer 220 on the blanket conductive layer 210, (2) performing a photolithography process to define a pattern required to form the contact pads 120, (3) performing an etching process to remove portions of the blanket conductive layer 210 exposed through the mask layer 220, and (4) removing the mask layer 220.

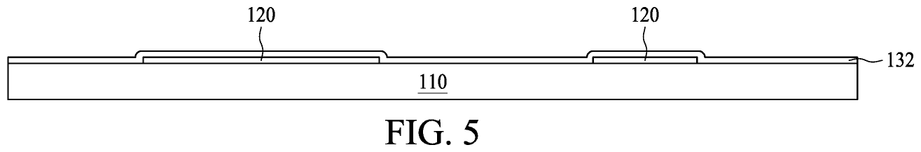

Referring to FIG. 5, in some embodiments, an underlying layer 132 is deposited to cover the multilayer component 110 and the contact pads 120 according to a step 208 in FIG. 2. In some embodiments, the underlying layer 132 is a substantially conformal layer. In some embodiments, the underlying layer 132 may include silicon dioxide (SiO₂). In some embodiments, the underlying layer 132 is formed, for example, using a CVD process or a spin coating process.

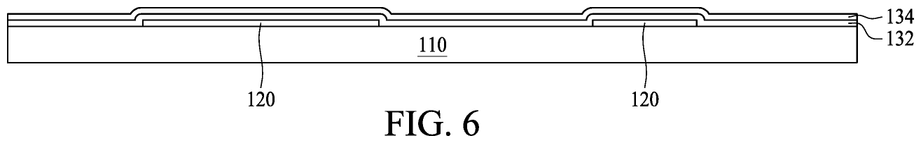

Referring to FIG. 6, in some embodiments, an overlying layer 134 is deposited on the underlying layer 132 according to a step 210 in FIG. 2. In some embodiments, the overlying layer 134 includes silicon nitride (Si₃N₄). In some embodiments, the overlying layer 134 is a substantially conformal layer. In some embodiments, the overlying layer 134 is formed, for example, using a CVD process.

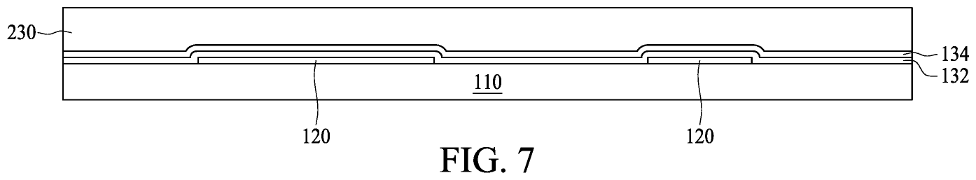

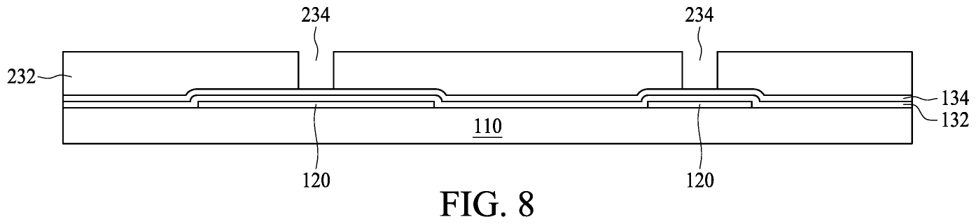

Referring to FIG. 7, in some embodiments, a first photoresist layer 230 is coated on the overlying layer 134 according to a step 212 in FIG. 2. In some embodiments, the first photoresist layer 230 fully covers the overlying layer 134. The first photoresist layer 230 is then patterned to define one or more regions where the overlying layer 134 and the underlying layer 132 are to be subsequently etched. In some embodiments, the first photoresist layer 230 is patterned by steps including (1) exposing the first photoresist layer 230 to a pattern (not shown), (2) performing a post-exposure back process, and (3) developing the first photoresist layer 230, thereby forming a first photoresist pattern 232 having one or more first openings 234, as shown in FIG. 8. In some embodiments, a portion of the overlying layer 134 to be subsequently etched is exposed through the first openings 234. In some embodiments, the first openings 234 are directly over the contact pads 120.

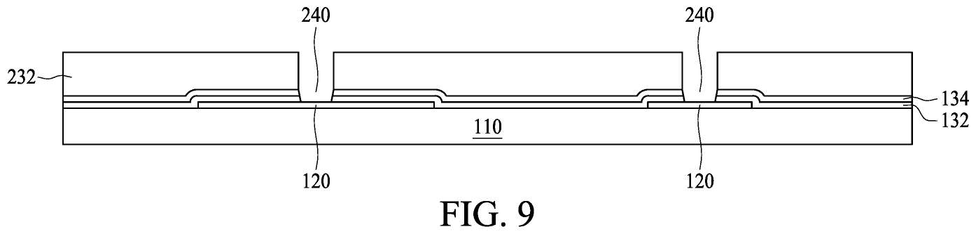

Referring to FIG. 9, in some embodiments, a first etching process is performed to etch the overlying layer 134 and the underlying layer 132 and thus create one or more first holes 240 according to a step 214 in FIG. 2. In some embodiments, portions of the contact pads 120 are exposed through the first holes 240. In some embodiments, the first etching process includes a wet etching process, a dry etching process, or a combination thereof.

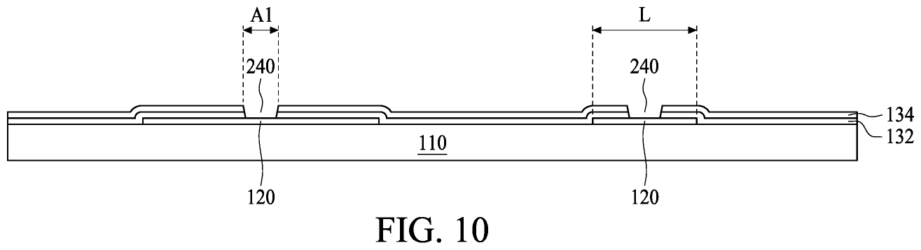

Referring to FIG. 10, after the first etching process, the first photoresist pattern 232 is removed according to a step 216 in FIG. 2. In some embodiments, an ashing process or a wet strip process may be used to remove the first photoresist pattern 232, wherein the wet strip process may chemically alter the first photoresist pattern 232 so that it no longer adheres to the overlying layer 134. In some embodiments, the first holes 240 have a first aperture A1 (e.g., a top or a maximum aperture), which is less than a length L of the contact pad 120. In some embodiments, the first aperture A1 is, for example, in a range between 1.0 and 2.5 μm. In some embodiments, the first aperture A1 gradually increases at positions of increasing distance from the contact pads 120.

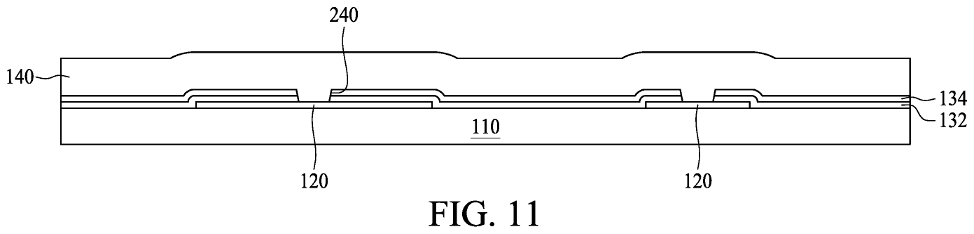

Referring to FIG. 11, in some embodiments, a dielectric layer 140 is conformally deposited on the overlying layer 134 and into the first holes 240 according to a step 218 in FIG. 2. In some embodiments, the dielectric layer 140 extends along a top surface 1342 of the overlying layer 134 and into the first holes 240. In some embodiments, the dielectric layer 140 includes silicon dioxide. In some embodiments, the dielectric layer 140 is formed, for example, using a CVD process.

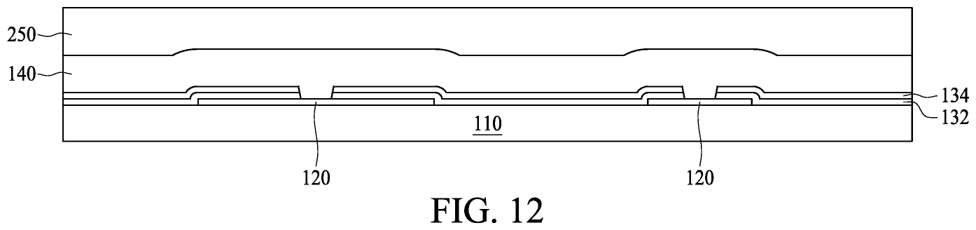

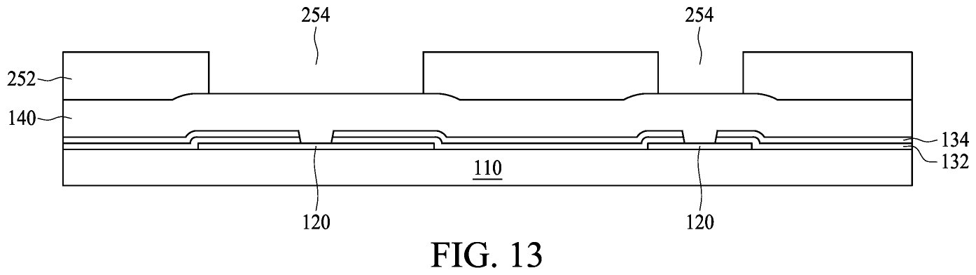

Referring to FIGS. 12 and 13, in some embodiments, a second photoresist layer 250 is coated on the dielectric layer 140 according to a step 220 in FIG. 2. In some embodiments, the second photoresist layer 250 fully covers the dielectric layer 140. The second photoresist layer 250 is then patterned to define one or more regions where the dielectric layer 140 is to be subsequently etched. In some embodiments, the second photoresist layer 250 is patterned by steps including (1) exposing the second photoresist layer 230 to a pattern (not shown), (2) performing a post-exposure back process, and (3) developing the second photoresist layer 250, thereby forming a second photoresist pattern 252 having one or more second openings 254 over the contact pads 120. In some embodiments, a portion of the dielectric layer 140 to be subsequently etched is exposed through the second openings 254. In some embodiments, the first etching process includes a wet etching process, a dry etching process, or a combination thereof.

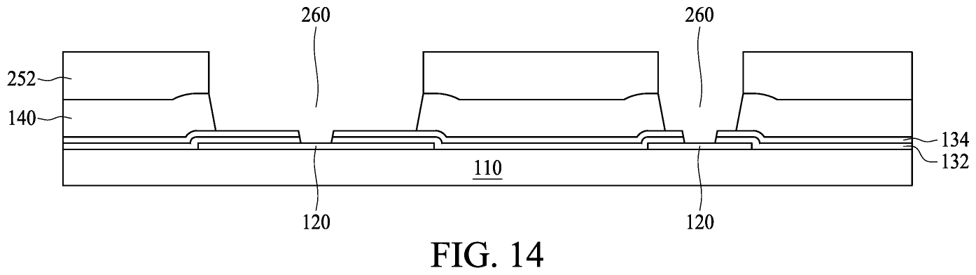

Referring to FIG. 14, in some embodiments, a second etching process is performed to uncover the contact pads 120 according to a step 222 in FIG. 2. In some embodiments, the contact pads 120 are uncovered by selectively removing a portion of the dielectric layer 140 exposed through the second photoresist pattern 252; accordingly, the first holes 240 are reopened, and one or more second holes 260 are formed penetrating through the dielectric layer 140 and communicating with the first holes 240, respectively. In some embodiments, the second etching process includes a wet etching process, a dry etching process, or a combination thereof.

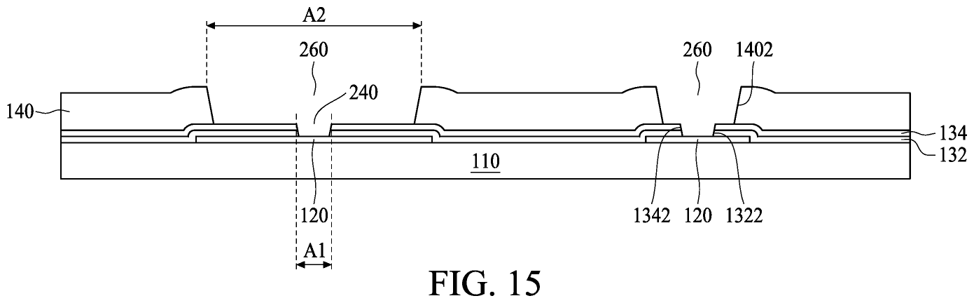

Referring to FIG. 15, after the second etching process, the second photoresist pattern 252 is removed according to a step 224 in FIG. 2. In some embodiments, an ashing process or a wet strip process may be used to remove the second photoresist pattern 252, wherein the wet strip process may chemically alter the second photoresist pattern 252 so that it no longer adheres to the dielectric layer 140. In some embodiments, the second holes 260 have a second aperture A2 greater than the first aperture A1. In some embodiments, the second aperture A2 is in a range between 8.0 and 10.0 μm. In some embodiments, the second aperture A2 gradually increases at positions of increasing distance from the contact pads 120. In some embodiments, the remaining underlying layer 132 has a sidewall 1322, the remaining overlying layer 134 has a sidewall 1342 continuous with the sidewall 1322, and the remaining dielectric layer 140 has a sidewall 1402 discontinuous with the sidewall 1342.

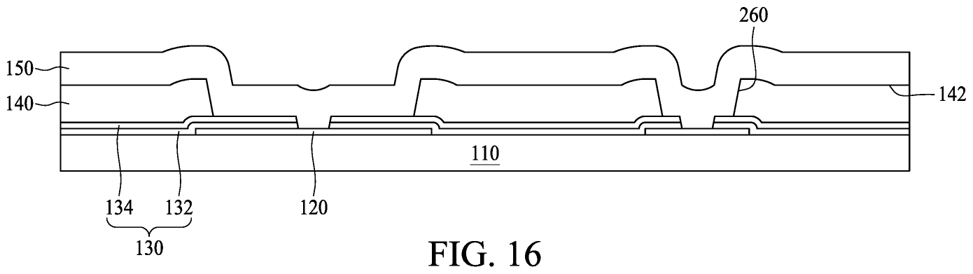

Referring to FIG. 16, in some embodiments, a metallic layer 150 is conformally deposited on the dielectric layer 140 and into the first holes 240 and the second holes 260 according to a step 226 in FIG. 2. In some embodiments, the metallic layer 150 is physically connected to the contact pads 120. In some embodiments, the metallic layer 150 includes copper or aluminum. In some embodiments, the metallic layer 150 is formed using a physical vapor deposition (PVD) process or a sputtering process.

In the present disclosure, a space (or “contact hole”) for filling the metallic layer 150 is constituted of the first hole 240 having the first aperture A1 and the second hole 260 having the second aperture A2 greater than the first aperture A1. Thus, the problems of poor step coverage of the metallic layer 150 are avoided, and a good ohmic contact is secured.

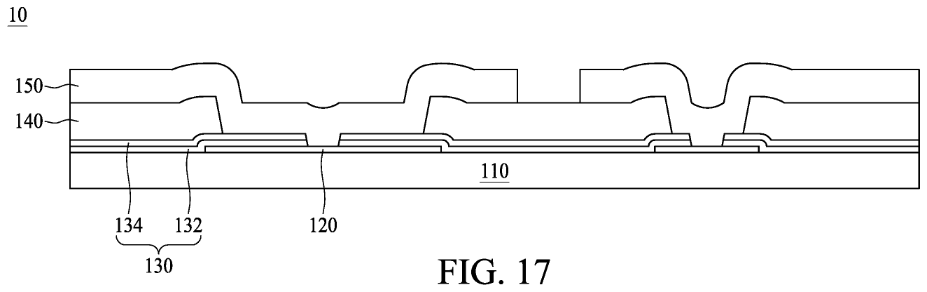

Referring to FIG. 17, in some embodiments, a patterning process is performed to define circuit routes on the metallic layer 150 according to a step 228 in FIG. 2. Accordingly, the electronic device 10 is completely formed. In some embodiments, the circuit routes may facilitate electrical coupling between the electronic device 10 and external devices.

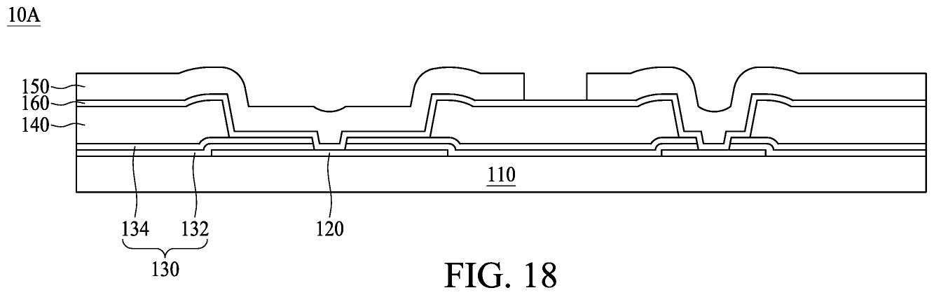

FIGS. 18 through 20 illustrate the formation of an electronic device 10A in accordance with alternative embodiments. Unless specified otherwise, the materials and formation methods of the components in these embodiments are essentially the same as those of the like components, which are denoted by like reference numerals in the embodiments shown in FIGS. 3 through 17. The details of the like components shown in FIGS. 18 through 20 may thus be found in the discussion of the embodiments shown in FIGS. 3 through 17.

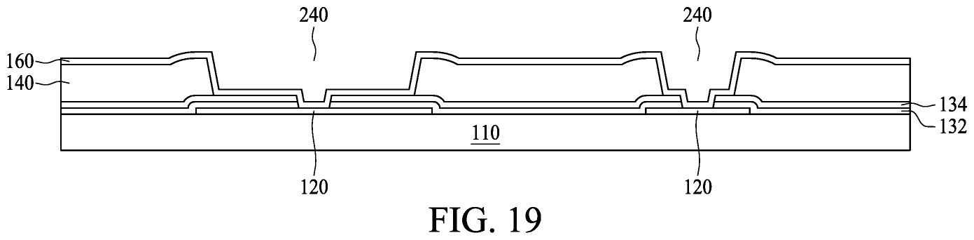

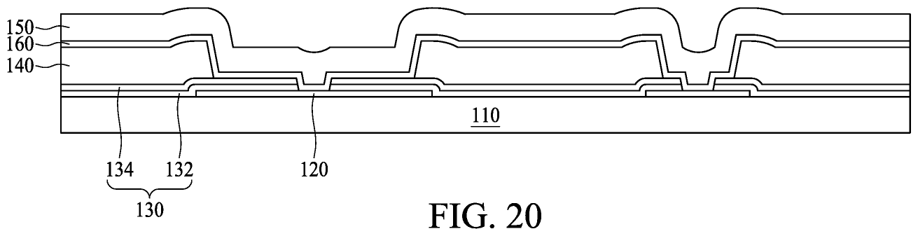

Referring to FIG. 18, in some embodiments, the electronic device 10A further includes a diffusion barrier layer 160 disposed at interfaces between the dielectric layer 140 and the metallic layer 150, between the overlying layer 134 and the metallic layer 150, between the underlying layer 132 and the metallic layer 150, and between the contact pads 120 and the metallic layer 150. The formation process of the electronic device 10A is similar to the process for forming the electronic device 10, except the formation of the electronic device 10A is started after the second holes 260 are formed and the first holes 240 are reopened, and before the circuit routes are defined. For example, FIGS. 19 and 20 illustrate cross-sectional views of intermediate stages in the formation of the electronic device 10A shown in FIG. 18.

Referring to FIG. 19, in some embodiments, after formation of the second holes 260, a diffusion barrier layer 160 is deposited on the dielectric layer 140 and into the second holes 260 and the first holes 240 according to a step 225 in FIG. 3. In some embodiments, the diffusion barrier layer 160 is in contact with the contact pads 120. In some embodiments, the diffusion barrier layer 160 is a substantially conformal layer. In some embodiments, the diffusion barrier layer 160 may improve adhesion of a metallic material 150, which is to be formed during a subsequent process, to the dielectric layer 140. In some embodiments, refractory metals, refractory metal nitrides, refractory metal silicon nitrides and combinations thereof are typically used for the diffusion barrier layer 160. In some embodiments, the diffusion barrier layer 160 may include titanium (Ti), titanium nitride (TiN), tantalum (Ta), tantalum nitride (TaN), titanium silicon nitride (TiSN), tantalum silicon nitride (TaSiN), or the like. In some embodiments, the diffusion barrier layer 160 is formed using a PVD process or an atomic layer deposition process, for example.

Referring to FIG. 20, in some embodiments, the metallic layer 150 is deposited on the diffusion barrier layer 160 according to a step 226 in FIG. 2. In some embodiments, the metallic layer 150 is a substantially conformal layer. The process steps and the material for forming the metallic layer 150 may be found by referring to the embodiments shown in FIG. 16. Next, as shown in FIG. 18, circuit routes are formed in the metallic layer 150, and hence the electronic device 10A is completely formed.

In conclusion, with the configuration of the electronic device 10/10A, the step coverage of the metallic layer 150 is improved since aspect ratios of a space, constituted of the first hole 240 and the second hole 260, for filling the metallic layer 150 discretely changes. Thus, the problems of poor step coverage of the metallic layer 150 are avoided, and a good ohmic contact is secured.

One aspect of the present disclosure provides an electronic device. The electronic device includes a multilayer component, at least one contact pad, a passivation layer, a dielectric layer, and a metallic layer. The contact pad is disposed on the multilayer component, the passivation layer covers the multilayer component and the contact pad, and the dielectric layer is disposed on the passivation layer. The metallic layer penetrates through the dielectric layer and the passivation layer and is connected to the contact pad. The metallic layer discretely tapers at positions of decreasing distance from the contact pad.

One aspect of the present disclosure provides a method of manufacturing an electronic device. The method includes steps of providing a multilayer component; forming at least one contact pad on the multilayer component; depositing a passivation layer on the multilayer component and the contact pad; creating at least one first hole in the passivation layer to expose the contact pad; depositing a dielectric layer on the passivation layer and into the first hole; removing a portion of the dielectric layer to uncover the contact pad and create at least one second hole in the dielectric layer, wherein a portion of a top surface of the passivation layer is exposed through the second hole, and depositing a metallic layer on the contact pad and the dielectric layer.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. An electronic device, comprising:
a multilayer component;
at least one contact pad disposed on the multilayer component;
a passivation layer covering the multilayer component and the contact pad;
a dielectric layer disposed on the passivation layer; and
a metallic layer penetrating through the dielectric layer and the passivation layer and connected to the contact pad, wherein the metallic layer comprises a first plug segment disposed in the passivation layer and in contact with the contact pad;
wherein the first plug segment of the metallic layer discretely tapers at positions of decreasing distance from the contact pad.

2. The electronic device of claim 1, wherein the metallic layer comprises:
a second plug segment disposed in the dielectric layer and connected to the first plug segment,
wherein the first plug segment has a first width less than a second width of the second plug segment,
wherein the second plug segment of the metallic layer discretely tapers at positions of decreasing distance from the contact pad.

3. The electronic device of claim 2, wherein the first width is in a range between 1.0 and 2.5 μm, and the second width is not less than 5.0 μm.

4. The electronic device of claim 2, wherein the metallic layer further comprises a pad segment disposed on the dielectric layer and connected to the second plug segment.

5. The electronic device of claim 4, wherein the metallic layer is a conformal layer.

6. The electronic device of claim 4, wherein the first plug segment, the second plug segment, and the pad segment are integrally formed.

7. The electronic device of claim 1, wherein the passivation layer comprises:
an underlying layer disposed on the multilayer component and the contact pad; and
an overlying layer disposed between the underlying layer and the dielectric layer.

8. The electronic device of claim 7, wherein at least one of the underlying layer and the overlying layer has a thickness in a range between 0.8 and 1.0 μm, and the dielectric layer has a thickness in a range between 4.0 and 6.0 μm.

9. The electronic device of claim 7, wherein sidewalls of the dielectric layer and the overlying layer interfaced with the metallic layer are discontinuous.

10. The electronic device of claim 9, wherein a sidewall of the underlying layer interfaced with the metallic layer is continuous with the sidewall of the overlying layer.

11. A method of manufacturing an electronic device, comprising:
providing a multilayer component;
forming at least one contact pad on the multilayer component;
depositing a passivation layer on the multilayer component and the contact pad;
creating at least one first hole in the passivation layer to expose the contact pad, wherein the first hole includes an aperture gradually increasing at positions of increasing distance from the contact pad;
depositing a dielectric layer on the passivation layer and into the first hole;
removing a portion of the dielectric layer to uncover the contact pad and create at least one second hole in the dielectric layer, wherein a portion of a top surface of the passivation layer is exposed through the second hole; and
depositing a metallic layer on the contact pad and the dielectric layer.

12. The method of claim 11, wherein the second hole communicates with the first hole.

13. The method of claim 12, further comprising conformally depositing a diffusion barrier layer on dielectric layer and into the second hole and the first hole.

14. The method of claim 11, wherein the second hole includes an aperture gradually increasing at positions of increasing distance from the contact pad.

15. The method of claim 14, wherein the aperture of the first hole is in a range between 1.0 and 2.5 μm, and the aperture of the second hole is in a range between 8.0 and 10.0 μm.

16. The method of claim 11, wherein the depositing of the passivation layer comprises:
depositing an underlying layer to cover the multilayer component; and
depositing an overlying layer on the underlying layer.
